(19) United States
(12) Patent Application Publication
(10) Pub. No.: US 2025/0274090 A1
(43) Pub. Date: Aug. 28, 2025

(54) AMPLIIFIER WITH COMMON MODE GAIN REDUCTION

(71) Applicant: TEXAS INSTRUMENTS INCORPORATED, Dallas, TX (US)

(72) Inventors: Abhijith N, Bangalore (IN); Neeraj Shrivastava, Bangalore (IN)

(21) Appl. No.: 18/589,561

(22) Filed: Feb. 28, 2024

(51) Int. Cl. H03F 3/45; H03G 1/00

(52) U.S. Cl. CPC H03F 3/45744; H03F 3/45183; H03F 3/45273; H03G 1/0029

(57) ABSTRACT

An amplifier circuit includes a first transistor having a terminal and a second transistor having a terminal coupled to the terminal of the first transistor. A third transistor has a first terminal coupled to the terminals of the first and second transistors and has a control terminal. A fourth transistor has a control terminal coupled to the terminals of the first and second transistors and to the first terminal of the third transistor. The fourth transistor has a second terminal. A fifth transistor has a control terminal coupled to the second terminal of the fourth transistor and has second and third terminals. A sixth transistor has a control terminal coupled to the control terminal of the third transistor and to the third terminal of the fifth transistor. The sixth transistor has a second terminal coupled to the second terminal of the fifth transistor.

### BACKGROUND

Numerous systems employ differential signaling which includes a pair of identical, but opposite phase, signals. Many systems may include a differential amplifier to amplify a differential input voltage. The common mode gain of an amplifier is the ratio of the change in the common mode voltage at the amplifier's output to a change in the common mode voltage at the amplifier's input. The design of differential amplifiers may take into account multiple factors including, for example, the power consumption of the amplifier, the noise produced by the amplifier, and the common mode gain of the amplifier.

### SUMMARY

In one example, an amplifier circuit includes a first transistor having a terminal and a second transistor having a terminal coupled to the terminal of the first transistor. A third transistor has a first terminal coupled to the terminals of the first and second transistors and has a control terminal. A fourth transistor has a control terminal coupled to the terminals of the first and second transistors and to the first terminal of the third transistor. The fourth transistor has a second terminal. A fifth transistor has a control terminal coupled to the second terminal of the fourth transistor and has second and third terminals. A sixth transistor has a control terminal coupled to the control terminal of the third transistor and to the third terminal of the fifth transistor. The sixth transistor has a second terminal coupled to the second terminal of the fifth transistor.

In another example, a data converter includes a first stage circuit, a second stage circuit, and an amplifier. The first stage circuit has an output. The second stage circuit has an input coupled to the output of the first stage circuit. The amplifier has an input coupled to the output of the first stage and has an output coupled to the input of the second stage. The amplifier includes first, second, third, fourth, fifth, and sixth transistors. The first transistor has a first terminal and a control terminal. The control terminal of the first transistor is coupled to the input of the amplifier. The second transistor has a first terminal coupled to the first terminal of the first transistor and has a control terminal coupled to the input of the amplifier. The third transistor has a first terminal coupled to the first terminals of the first and second transistors and has a control terminal. The fourth transistor has a control terminal coupled to the first terminals of the first and second transistors and to the first terminal of the third transistor. The fourth transistor has a second terminal. The fifth transistor has a control terminal coupled to the second terminal of the fourth transistor and has second and third terminals. The sixth transistor has a control terminal coupled to the control terminal of the third transistor and to the third terminal of the fifth transistor. The sixth transistor has a second terminal coupled to the second terminal of the fifth transistor.

In yet another example, a data converter includes a first stage circuit, a second stage circuit, and an amplifier. The first stage circuit has an output. The second stage circuit has an input coupled to the output of the first stage circuit. The amplifier has an input coupled to the output of the first stage circuit and has an output coupled to the input of the second stage. The amplifier includes first, second, and third transistors and a tail current control circuit. The first transistor has a first terminal and has a control terminal coupled to the input of the amplifier. The second transistor has a first terminal coupled to the first terminal of the first transistor and has a control terminal coupled to the input of the amplifier. The third transistor has a first terminal coupled to the first terminals of the first and second transistors and has a control terminal. The tail current control circuit has a first terminal coupled to the control terminal of the third transistor and has a second terminal coupled to the first terminals of the first and second transistors. The tail current control circuit is configured to adjust a tail current through the third transistor based on a voltage at the first terminals of the first and second transistors.

### BRIEF DESCRIPTION OF THE DRAWINGS

FIG. 1 is a block diagram of a data converter, in an example.

FIG. 2 is a schematic diagram of an amplifier usable in the data converter of FIG. 1, the amplifier including tail current control circuits, in an example.

FIG. 3 is a schematic diagram of the tail current control circuit of FIG. 2, in an example.

FIG. 4 is a schematic diagram of the tail current control circuit of FIG. 2, in another example.

FIG. 5 is a schematic diagram of the tail current control circuit 250 useful at higher frequencies, in an example.

FIG. 6 is a schematic diagram of a tail current control circuit including the features of the examples of FIGS. 3, 4, and 5 to reduce the common gain across a wide range of frequencies.

FIG. 7 is a schematic diagram of tail current control circuit, in another example.

### DETAILED DESCRIPTION

The same reference numbers or other reference designators are used in the drawings to designate the same or similar (either by function and/or structure) features.

The examples described herein pertain to a dynamic differential amplifier with a relatively low common mode gain. Such amplifiers may be used, for example, in a data converter, such as an analog-to-digital converter (ADC). However, the principles described herein may apply to other types of differential amplifiers as well as other types of systems besides data converters.

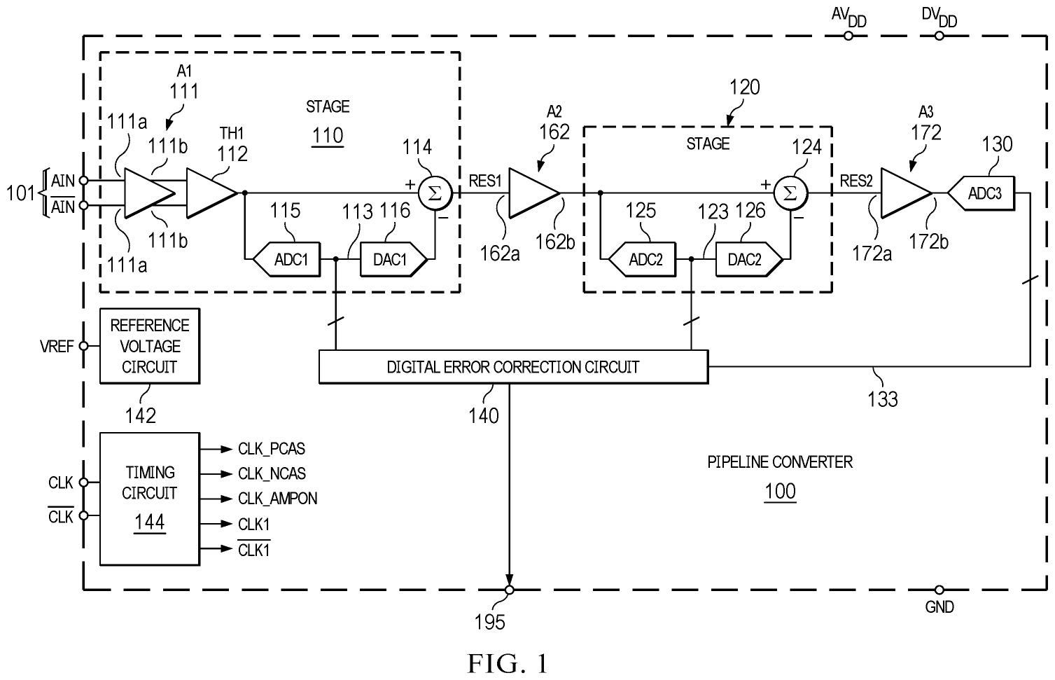

FIG. 1 is a block diagram of an ADC 100, in an example. In this example, ADC 100 is a pipeline converter including stages 110, 120, and 130, amplifiers A2 162 and A3 172, a digital error correction circuit 140, a reference voltage circuit 142, and a timing circuit 144. ADC 100 includes differential input terminals 101 and has a digital output terminal 195. ADC 100 converts a differential analog input voltage (AIN-A̅I̅N̅) provided at its differential input terminals 101 into a multi-bit (e.g., 13 bits) digital output value, D at its digital output terminal 195. Stage 110 includes an amplifier A1 111, a track and hold circuit (TH1) 112, a flash analog-to-digital converter ADC1 115, a digital-to-analog converter (DAC) DAC1 116, and a summer 114. Amplifier A1 has a differential input 111a coupled to differential input terminals 101 and has a differential output 111b coupled to the input of TH1 112. TH1 112 converts a continuous time signal at its input to a sampled domain signal at its output. The output of TH1 is coupled to a positive (+) input of summer 114 and to an input of flash ADC1 115. Flash ADC1 115 has an output coupled to an input of DAC1 116, and the output of DAC1 116 is coupled to a negative (−) input of summer 114. Flash ADC1 115 may be a low-resolution ADC, e.g., a one, two, or three-bit ADC, and, accordingly, provides a relatively low-resolution digital equivalent (bits 113) of the output of amplifier A1 111 during a sample phase of stage 110. The digital DAC1 116 converts the digital value represented by bits 113 from flash ADC1 115 to an analog equivalent signal of the digital equivalent. Summer 114 subtracts the analog signal from DAC1 116 from the analog output of TH1 112 to produce a residue voltage RES1 at its output. Bits 113 from ADC1 115 are provided to digital error correction circuit 140.

The residue signal RES1 is provided to an input 162a (e.g., a differential input) of amplifier A2 162. During a hold phase, amplifier 162 amplifies the residue signal RES1 from stage 110. The output 162b of amplifier A2 is coupled to stage 120. Stage 120 is configured similar to stage 110. Stage 120 includes a flash ADC2 125, a DAC2 126, and a summer 124. The amplified residue signal from amplifier 162 is provided to the positive input of summer 124 and to an input of flash ADC2 125. During a sample phase for stage 120, flash ADC2 125 produces additional bits 123 (e.g., 1, 2, 3, etc.) bits of the digital output code and provides those bits to digital error correction circuit 140. The output of flash ADC2 125 is also coupled to an input of DAC2 126, and the output of DAC2 126 is coupled to the negative input of summer 124. DAC2 126 converts the digital value represented by bits 123 to an analog signal equivalent. Summer 124 produces another residue signal RES2 based on the differences between the amplified residue from the first stage 110 and the analog signal from DAC2 126.

Amplifier A3 172 includes an input 172a (e.g., a differential input) and an output 172b. Input 172a is coupled to the output of summer 124. During a hold phase, amplifier A3 172 amplifies the residue signal RES2 from second stage 120 and provides an amplified residue signal to third stage 130. In the example of FIG. 1, third stage 130 includes ADC3 130, which converts the amplified residue from amplifier A3 to the remaining (e.g., lowest order) bits 133 of the digital code equivalent of the differential input signal AIN/A̅I̅N̅. In some examples, ADC3 130 may include a delay domain ADC.

Digital error correction circuit 140 provides one or more corrections to the digital code represented by bits 113, 123, and 133 to improve (e.g., increase) the signal-to-noise ratio (SNR) of ADC 100. Digital error correction circuit 140 provides the corrected digital code to digital output terminal 195.

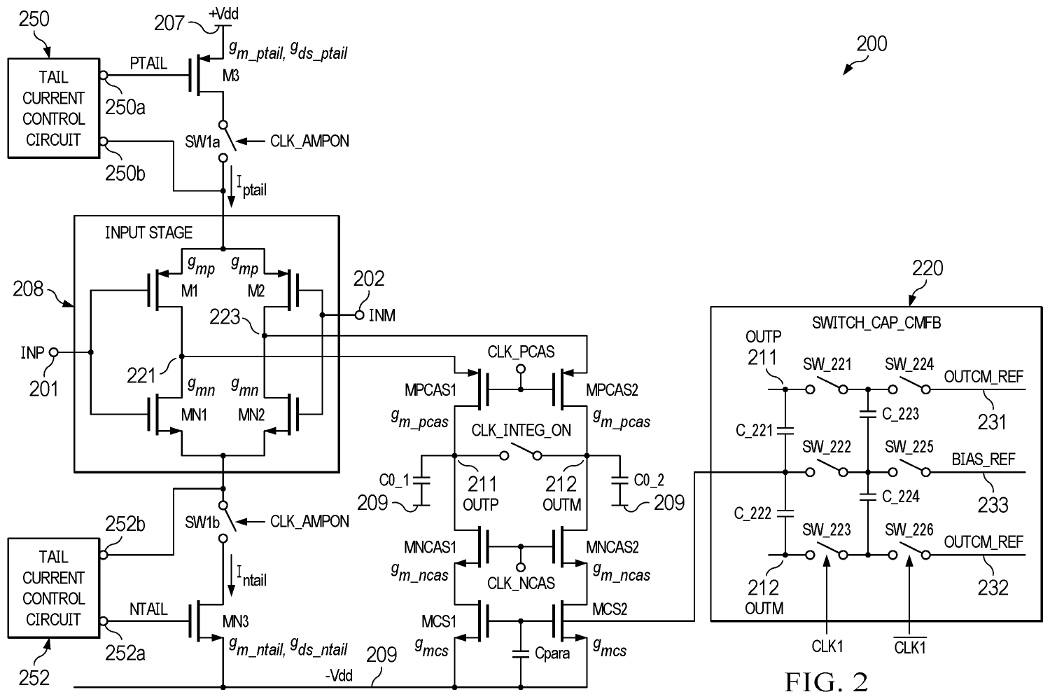

Reference voltage circuit 142 produces one or more reference voltages for use by ADC1 115, ADC2 125, and ADC3 in stage 130. Timing circuit 144 produces one or more clock signals (clocks) for use to control the various circuits of ADC 100. For example, timing circuit 144 generates clocks CLK_PCAS, CLK_NCAS, CLK_AMPON, CLK1, and C̅L̅K̅1̅, whose uses are shown and described below with respect to FIG. 2. Clock C̅L̅K̅1̅ is an inverse of CLK1 (e.g., 180 degrees out of phase with respect to each other). Timing circuit 144 may generate a separate clock CLK_AMPON for each of amplifiers A2 and A3.

In some examples, amplifier A1 is a continuous-time amplifier, and amplifiers A2 and A3 are dynamic integrating amplifiers. A continuous-time amplifier continuously amplifies its input signal. A dynamic integrating amplifier is turned on during each hold phase and turned off when not in the hold phase.

FIG. 2 is a schematic diagram of an amplifier 200, in an example. Amplifier 200 can be used to implement, for example, either or both of amplifiers A2 162 or A3 172, which, as noted above, are dynamic integrating amplifiers. Amplifier 200 includes an input stage 208, switches SW1a and SW1b, a switched capacitor common-mode feedback (CMFB) circuit 220, tail current control circuits 250 and 252, and transistors M3, MN3, MPCAS1, MPCAS2, MNCAS1, MNCAS2, MCS1, and MCS2. Input stage 208 includes transistors M1, M2, MN1, and MN2. In this example, transistors M1, M2, M3, MPCAS1, and MPCAS2 are p-channel field effect transistors (PFETs) and transistors MN1, MN2, MN3, MNCAS1, MNCAS2, MCS1, and MCS2 are n-channel field effect transistors (NFETs). Capacitance Cpara between the gates of transistors MCS1/MCS2 and the voltage supply terminal 209 represents a parasitic capacitance of transistors MCS1 and MCS2 including, for example, their gate-to-source capacitance and drain-to-source capacitance.

The source terminals (or sources) of transistors M1 and M2 are coupled together and, through switch SW1a, to the drain terminal (or drain) of transistor M3. Similarly, the sources of transistors MN1 and MN2 are coupled together and, through switch SW1b, to the drain of transistor MN3. Switches SW1a and SW1b are controlled based on clock CLK_AMPON from timing circuit 144. Amplifier 200 in this example is a dynamic integrating amplifier, which is turned on during each hold phase and turned off when not in the hold phase. When switches SW1a and SW1b are closed (turned on), amplifier 200 is on and amplifies its differential input, INP-INM, to produce a differential output, OUTP-OUTM. When switches SW1a and SW1b are open (turned off), the amplifier is off and consumes little or no power. Accordingly, amplifier 200 can be turned off to save power. In one example, each of amplifiers A2 162 and A3 172 can be turned off during a portion of each cycle of the respective stage 110 and 120. For example, amplifier A2 162 is turned off while stage 110 is beginning to generate residue signal RES1. Upon residue signal RES1 settling, timing circuit 144 asserts clock signal CLK_AMPON to a logic state to turn on amplifier A2 162 to cause amplifier A2 to amplify RES1. Similarly, timing circuit 144 turns on amplifier A3 upon residue signal RES2 from stage 120 settling.

The current through transistor M3 to the sources of transistors M1 and M2 is tail current Iₚₜₐᵢₗ. Current Iₚₜₐᵢₗ is the sum of a direct current (DC) current plus a “small signal” current iₚₜₐᵢₗ. Small signal current iₚₜₐᵢₗ represents the change in the tail current Iₚₜₐᵢₗ due to a change in the common mode voltage. Similarly, current Iₙₜₐᵢₗ through transistor MN3 also includes a DC component and a small signal component, iₙₜₐᵢₗ. While DC tail currents should persist through transistors M3 and MN3 when switches SW1a and SW1b are closed, the small signal current components, iₚₜₐᵢₗ, and iₙₜₐᵢₗ should be small or zero. A small or zero common mode gain for the amplifier means that currents iₚₜₐᵢₗ and iₙₜₐᵢₗ advantageously are small or zero.

The sources of transistors M3 and MN3 are coupled to respective voltage supply terminals 207 (e.g., +Vdd) and 209 (e.g., −Vdd). The differential input to amplifier 200 includes terminals 201 and 202. Terminals 201 and 202 may correspond to input 162a of amplifier A2 162 and/or input 172a of amplifier A3 172. The gate terminals (or gates) of transistors M1 and MN1 are coupled together and to amplifier terminal 201. The gates of transistors M2 and MN2 are coupled together and to amplifier terminal 202. The drains of transistors M1 and MN1 are coupled together and are one output 221 of the input stage 208. Similarly, the drains of transistors M2 and MN2 are coupled together and are another output 223 of input stage 208. Output 221 is coupled to the source of transistor MPCAS1, and output 223 is coupled to the source of transistor MPCAS2.

The drains of transistors MPCAS1 and MNCAS1 are coupled together at amplifier output 211. The signal at amplifier output 211 is OUTP. An output capacitor C0_1 is coupled between amplifier output 211 and voltage supply terminal 209. Similarly, the drains of transistors MPCAS2 and MNCAS2 are coupled together at amplifier output 212. The signal at amplifier output 212 is OUTN. An output capacitor C0_2 is coupled between amplifier output 212 and voltage supply terminal 209. Amplifier outputs 221 and 212 may correspond to output 162b of amplifier A2 162 and/or out 172b of amplifier A3 172. The capacitance of capacitors C0_1 and C0_2 may be the same and is referred to herein as “C0.” The source of transistor MNCAS1 is coupled to the drain of transistor MCS1, and the source of transistor MNCAS2 is coupled to the drain of transistor MCS2. The sources of transistors MCS1 and MCS2 are coupled to voltage supply terminal 209.

The gates of transistors MPCAS1 and MPCAS2 are coupled together and receive clock CLK_PCAS from the timing circuit 144. The gates of transistors MNCAS1 and MNCAS2 are coupled together and receive clock CLK_NCAS from the timing circuit 144. The gates of transistors MCS1 and MCS2 are coupled together and to switched capacitor CMFB circuit 220. In the example of FIG. 2, switched capacitor CMFB circuit 220 includes a capacitor network which includes capacitors C_221, C_222, C_223, and C_224 and switches SW_221, SW_222, SW_223, SW_224, SW_225, and SW_226. Switches SW_221 and SW_224 are coupled in series between amplifier output 212 and a reference terminal 231 having a reference voltage OUTCM_REF. Similarly, switches SW_223 and SW_226 are coupled in series between amplifier output 211 and a reference terminal 232 also having reference voltage OUTCM_REF. Switches SW_222 and SW_225 are coupled in series between the gates of transistors MCS1 and MCS2 and terminal 233 which has another reference voltage BIAS_REF. Capacitor C_221 is coupled between amplifier output 211 and the gates of transistor MCS1 and MCS2. Capacitor C_222 is coupled between the gates of transistor MCS1 and MCS2 and amplifier output 212. Capacitors C_223 and C_224 are coupled in series as shown. Switches SW_221, SW_222, and SW_223 are operated according to clock CLK1, and switches SW_224, SW_225, and SW_226 are operated according to clock C̅L̅K̅1̅. Switched capacitor CMFB circuit 220 samples the common mode voltage at the output of amplifier 200, compares the sensed common mode output voltage to a reference voltage, and provides a voltage to the gates of transistors MCS1 and MCS2 to reduce or increase the output common-mode current at the output of amplifier 200 to thereby maintain a steady output common mode voltage.

Each transistor in FIG. 2 can be characterized according to one or more transconductance parameters. For example, transconductance gₘ for a transistor is the ratio of a change in its drain current (Id) due to a change in the gate-to-source voltage (Vgs). Transconductance g_{ds} for a transistor is the ratio of its drain current due to a change in its drain-to-source voltage (Vds). FIG. 2 lists various transconductances for its transistors. For example, the gₘ and g_{ds} for transistor M3 is g_{m_ptail} and g_{ds_ptail}, respectively. The gₘ and g_{ds} for transistor MN3 is g_{m_ntail} and g_{ds_ntail}, respectively. The gₘ for transistors M1 and M2 is gₘₚ (the same gₘ value). The gₘ for transistors MN1 and MN2 is gₘₙ. The gₘ for transistors MPCAS1 and MPCAS2 is g_{m_pcas}, and the gₘ for transistors MNCAS1 and MNCAS2 is g_{m_ncas}. The gₘ for transistors MCS1 and MCS2 is g_{mcs}.

ADC3 130 may be a delay domain ADC as noted above. Delay domain ADCs have relatively low common mode rejection ratios (CMRRs) which makes them sensitive to variation in input common mode voltage. Amplifier 200, if used to implement, for example, amplifiers A2 162 and/or A3 172, advantageously generates relatively little noise and consumes relatively little power. However, as explained below, absent the tail current control circuits 250 and 252, amplifier 200 may not have a sufficiently low common mode gain (A_{cm}) to balance out the relatively low CMRR of delay domain ADC3 130.

The common mode gain of amplifier 200 can be derived based on the following equations.

$${G}_{m \_ out} = ( \frac{{g}_{mp}}{1 + {g}_{mp} / {g}_{ds \_ ptail}} ) + ( \frac{{g}_{mn}}{1 + {g}_{mn} / {g}_{ds \_ ntail}} ) \qquad ( Eq . 1 )$$

$${G}_{in} = \frac{{g}_{dsp} * {g}_{ds \_ ptail}}{{g}_{mp}} + \frac{{g}_{dsn} * {g}_{ds \_ ntail}}{{g}_{mn}} \qquad ( Eq . 2 )$$

$${G}_{outp} = ( \frac{{g}_{ds \_ pcas}}{{g}_{m \_ pcas}} ) {G}_{in} \qquad ( Eq . 3 )$$

$${G}_{outn} = {g}_{mcs} * A \qquad ( Eq . 4 )$$

where

$$A = ( \frac{2 C}{2 C + {C}_{para}} )$$

and C is the capacitance of capacitors C_221 through C_224 of the switched capacitor CMFB circuit 220.

$${G}_{out} = {G}_{outp} + {G}_{outn} \qquad ( Eq . 5 )$$

$${A}_{cm} = \frac{{G}_{m \_ out} * τ}{{C}_{o}} ( 1 - {e}^{- {T}_{int} / τ} ) \qquad ( Eq . 6 )$$

where, Tᵢₙₜ is the integration time of amplifier 200 and τ=Cₒ/Gₒᵤₜ.

The open loop gain (A_{oL}) of the switched capacitor CMFB circuit 220 is given by:

$${A}_{oL} = ( \frac{{g}_{mcs} * {T}_{int}}{{C}_{o}} ) A \qquad ( Eq . 7 )$$

The value of A_{oL} may be relatively low. For example, for illustrative values of g_{mcs} of 24 mS, a Tᵢₙₜ of 140 ps, C₀ of 2.9 pF, C of 200 fF, and Cₚₐᵣₐ of 180 fF, A_{oL} will be equal to 1.2 dB which is very low. The common mode gain A_{cm} is given by:

$${A}_{cm} = {G}_{m \_ out} * {R}_{0} [ 1 - exp ( - \frac{{T}_{int}}{{R}_{0}} * {C}_{0} ) ] \qquad ( Eq . 9 )$$

The output resistance R₀ of amplifier is the output resistance without the switched capacitor CMFB circuit 220 divided by (1+A_{oL}),

$${R}_{0} = \frac{{R}_{0}}{1 + {A}_{oL}} \qquad ( Eq . 10 )$$

For integration times that are less than the product of R₀ and C₀ (Tᵢₙₜ<<R₀*C₀),

$${A}_{cm} \approx {G}_{m \_ out} * {T}_{int} / {C}_{0} . \qquad ( Eq . 11 )$$

For integration times that are more than the product of R₀ and C₀ (Tᵢₙₜ>>R₀*C₀), then

$${A}_{cm} \approx {G}_{m \_ out} * {R}_{0} \qquad ( Eq . 12 )$$

Accordingly, if R₀ is high enough such that Tᵢₙₜ<<R₀*C₀, then per Eq. (11), A_{cm} can be reduced by reducing G_{m_out} because Tᵢₙₜ and C₀ are fixed by other requirements such as gain, power consumption, and noise. But, if R₀ is relatively low such that Tᵢₙₜ>>R₀*C₀, then per Eq. (12), A_{cm} will be proportional to R₀ and, accordingly, as R₀ is reduced, A_{cm} also reduces. The switched capacitor CMFB circuit 220 is used to reduce the output resistance R₀ per Eq. (10). However, the switch capacitor CMFB circuit 220 may not be able to reduce the output resistance R₀ enough to get a sufficiently low A_{cm}, and other techniques to reduce A_{cm} may be employed, as described below.

Tail current control circuits 250 and 252 are coupled to the respective gates of transistors M3 and MN3. Terminal 250a of tail current control circuit 250 is coupled to the gate of transistor M3, and terminal 252a of tail current control circuit 252 is coupled to the gate of transistor MN3. Terminal 250b of tail current control circuit 250 is coupled to the sources of transistors M1 and M2, and terminal 252b of tail current control circuit 252 is coupled to the sources of transistors MN1 and MN2. As described below, tail current control circuits 250 and 252 cause amplifier 200 to have a lower common mode gain than it otherwise would have without the tail current control circuits.

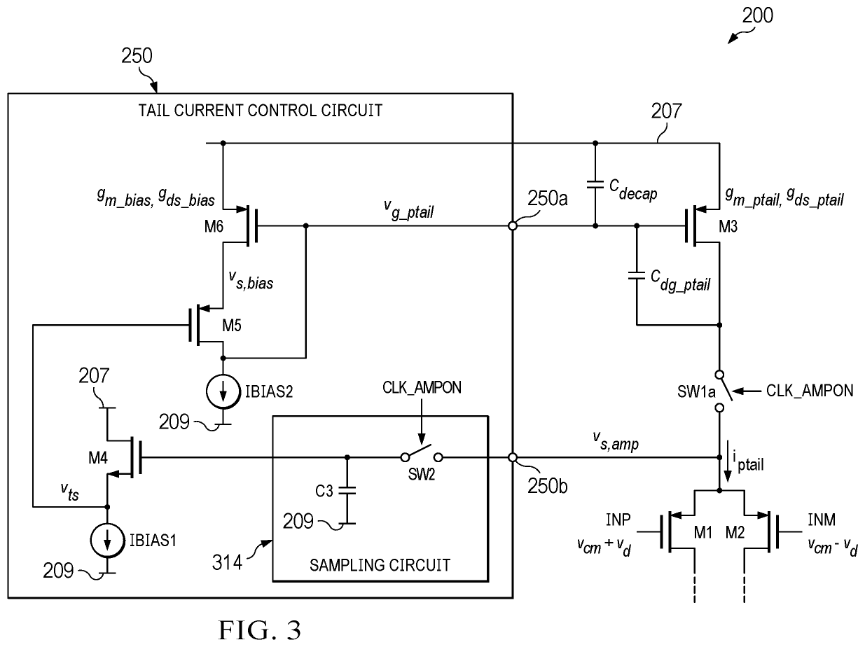

FIG. 3 is a schematic diagram of an example tail current control circuit 250 usable for amplifiers A2 162 and/or A3 172. In this example, tail current control circuit 250 includes transistors M4, M5, and M6, a sampling circuit 314, and current source circuits IBIAS1 and IBIAS2. Capacitor Cdecap is a capacitor between the source and gate of transistor M3 and may be included to reduce the noise of amplifier 200 which otherwise may occur due to fluctuations or switching noise on the power supply voltage at the voltage supply terminals 207. Capacitance C_{dg_ptail} is the parasitic drain-to-source capacitance of transistor M3. Sampling circuit 314 includes a capacitor C3 and a switch SW2. Transistor M4 is an NFET and transistors M5 and M6 are PFETs. The gate of transistor M6 is coupled to the gate of transistor M3 and to the drain of transistor M5. The source of transistor M6 is coupled to the voltage supply terminal 207. The drain of transistor M6 is coupled to the source of transistor M5. The gₘ and g_{ds} of transistor M6 is designated as g_{m,bias} and g_{ds,bias}, respectively, as shown in FIG. 3. The voltage on the gates of transistors M3 and M6 is V_{g_ptail}. A terminal of current source circuit IBIAS2 is coupled to the drain of transistor M5, and another terminal of current source circuit IBIAS2 is coupled to the voltage supply terminal 209. The gate of transistor M5 is coupled to the source of transistor M4. A terminal of current source circuit IBIAS1 is coupled to the source of transistor M4, and another terminal of current source circuit BIAS1 is coupled to the voltage supply terminal 209. The drain of transistor M4 is coupled to the voltage supply terminal 207. Switch SW2 is coupled between the sources of transistors M1/M2 and the gate of transistor M4. Capacitor C3 is coupled between the gate of transistor M4 and the voltage supply terminal 209.

The voltage at the gate of transistors M1 and M2 is the input common mode voltage V_{cm} plus or minus the differential input voltage V_{d}. The voltage at the gate of transistor M1 is V_{cm}+V_{d}, and the voltage at the gate of transistor M2 is V_{cm}−V_{d}. Per a small signal analysis, transistors M1 and M2 function as source followers. Accordingly, the voltage at the sources of transistors M1 and M2 is proportional to the common mode voltage. The voltage at the sources of transistors M1 and M2 is sampled by sampling circuit 314, e.g., by charging capacitor C3 to the voltage of the sources of transistors M1 and M2 when switch SW2 closes. Switch SW2 is controlled based on the same signal CLK_AMPON that closes switch SW1a.

The combination of transistor M4 and current source circuit IBIAS1 is such that transistor M4 is configured as a source-follower circuit. Accordingly, the voltage vₜₛ at the source of transistor M4 is the gate voltage of transistor M4 minus the threshold voltage Vₜₕ of transistor M4. Consequently, voltage Vₜₛ is proportional to the common mode voltage V_{cm}. Voltage vₜₛ also is the voltage at the gate of transistor M5.

The tail current control circuit 250 in FIG. 3 is explained with respect to a small signal analysis. Accordingly, the small signal tail current iₚₜₐᵢₗ is labeled in FIG. 3. A change in the common mode voltage V_{cm} causes a change in current iₚₜₐᵢₗ. For example, an increase in v_{cm} causes the small signal voltage v_{s,amp} on the sources of transistors M1 and M2 to increase. With respect to the g_{ds_ptail} of transistor M3, tail current iₚₜₐᵢₗ can be determined as:

$${i}_{ptail} = {v}_{s , amp} * {g}_{ds \_ ptail} \qquad ( Eq . 13 )$$

Small signal voltage v_{s,amp} is sampled by sampling circuit 314, e.g., by charging capacitor C3 to voltage v_{s,amp} when switch SW2 closes during the hold phase of the ADC. Voltage vₜₛ is the sampled voltage v_{s,amp} less the threshold voltage of transistor M4. Voltage vₜₛ is provided to the gate to transistor M5. As voltage vₜₛ increases, which will occur if v_{cm} increases, the voltage vs,bias (voltage on the source of transistor M5) also increases. The drain current through transistor M6 is proportional to the product of g_{ds,bias} and the voltage v_{s,bias} on the drain of transistor M6. Accordingly, an increase of the voltage on the drain of transistor M6 would tend to cause the drain current of transistor M6 to increase. However, the fixed current from current source circuit IBIAS2 prevents current through transistor M6 from changing. Accordingly, any change in the current through transistor M6 due to an increase in vs,bias will be balanced by an opposite polarity change in the current through transistor M6 resulting from its g_{m,bias} transconductance. If the current through transistor M6 attempts to increase as a result of an increase in voltage v_{s,bias}, the voltage v_{g_ptail} on the gate of transistor M6 will decrease to a level resulting in approximately no change in the small signal drain current through transistor M6. The voltage v_{g_ptail} on the gate of transistor M6 is also the gate voltage for transistor M3. With respect to the g_{m_ptail} transconductance of transistor M3, current iₚₜₐᵢₗ is proportional to the product of g_{m_ptail} and v_{g_ptail}. A decrease in voltage v_{g_ptail} causes a decrease in the current iₚₜₐᵢₗ through transistor M3. Accordingly, an increase in v_{cm} causes an increase in iₚₜₐᵢₗ and an increase in voltage vₜₛ. The increase in voltage vₜₛ causes a decrease in voltage v_{g_ptail} which then reduces the drain current through transistor M3 based on its g_{m_ptail} thereby advantageously counteracting the increase in current iₚₜₐᵢₗ resulting from the increase in v_{cm}. Similarly, a decrease in the common mode voltage V_{cm} causes a decrease in current iₚₜₐᵢₗ, which through tail current control circuit 250 causes an increase in voltage v_{g_ptail} to thereby counteract the decrease in current iₚₜₐᵢₗ and maintain iₚₜₐᵢₗ relatively constant

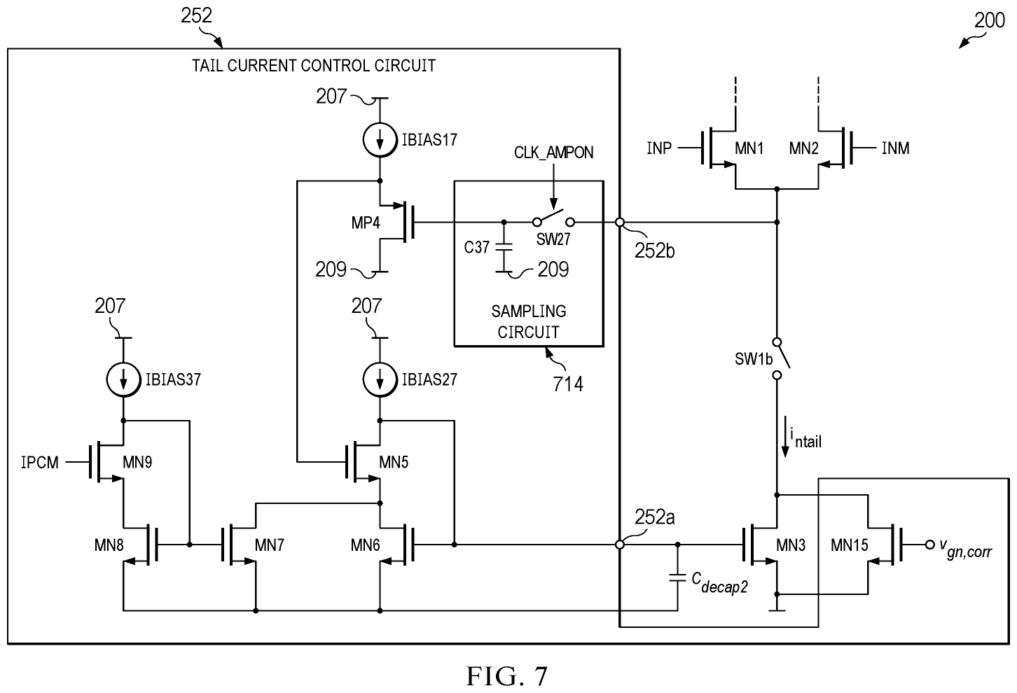

The voltage that is sampled by sampling circuit 314 to control the loop formed by tail current control circuit 250 is the voltage at the sources of transistors M1 and M2 during the ADC's hold phase. That voltage is the residue voltage, which advantageously is a relatively small voltage. The large differential signal across inputs INP and INM is not sensed or otherwise provided to tail current control circuit 250. The configuration of tail current control circuit 252 is the same or similar as tail current control circuit 250 and is shown and described below with respect to FIG. 7.

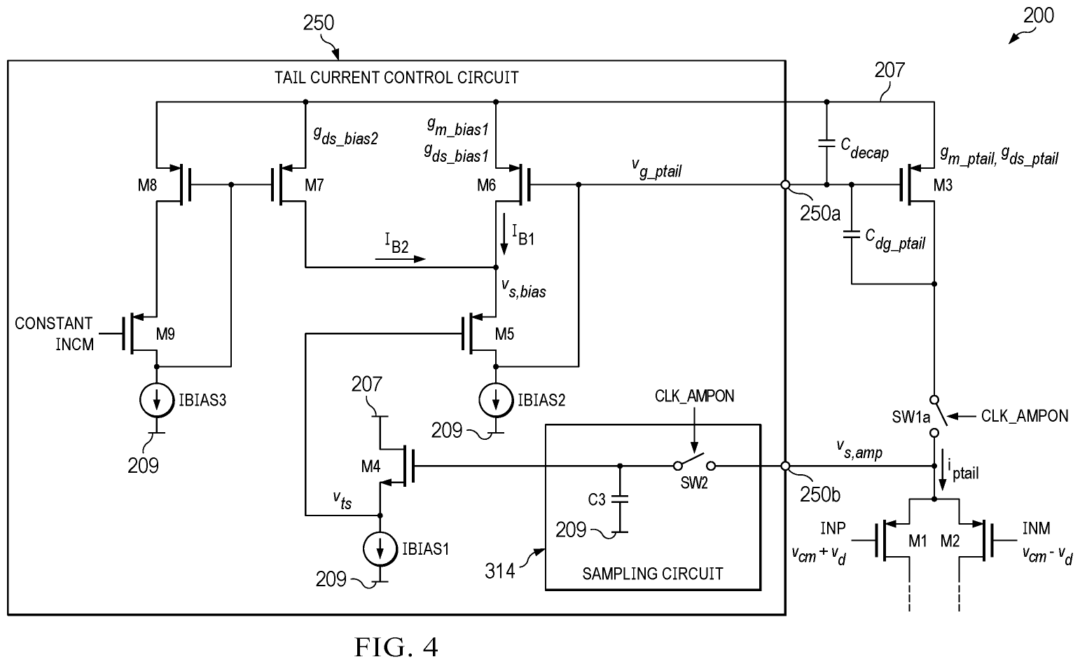

Because amplifier 200 is a dynamic amplifier (switch SW1a, SW1b turns on an off per CLK_AMPON), the ratio of C_{dg}_{ₚₜₐᵢₗ}/(C_{decap}+C_{dg_ptail}) results in some current iₚₜₐᵢₗ remaining despite the operation of the tail current control circuit 250 in FIG. 3. The gain of tail current control circuit 250 in FIG. 3 may not be sufficiently large to further reduce the current iₚₜₐᵢₗ. The gain of the loop formed by transistors M4-M6 in tail current control circuit 250 in FIG. 3 is given by the ratio g_{ds,bias}/g_{m,bias}. The remaining current iₚₜₐᵢₗ can be further reduced through the example tail current control circuit 250 of FIG. 4.

FIG. 4 is a schematic diagram of tail current control circuit 250 in another example. In the example of FIG. 4, tail current control circuit 250 includes transistors M4, M5, and M6, current source circuits IBIAS1 and IBIAS, and sampling circuit 314, as described above. The gₘ and g_{ds} of transistor M6 is relabeled in FIG. 4 as g_{m,bias1} and g_{ds,bias1}, respectively. Tail current control circuit 250 also includes transistors M7, M8, M9, and current source circuit IBIAS3. In this example, transistors M7-M9 are PFETs. The g_{ds} of transistor M7 is g_{ds,bias2}. The sources of transistors M6-M8 are coupled together. The drains of transistors M6 and M7 are coupled together and to the source of transistor M5. The gates of transistors M7 and M8 are coupled together and to the drain of transistor M9. The drain of transistor M8 is coupled to the source of transistor M9. A terminal of urrent source circuit IBIAS3 is coupled to the drain of transistor M9 and another terminal of current source circuit IBIAS3 is coupled to the voltage supply terminal 209.

A fixed bias voltage INCM is provided to the gate of transistor M9. The combination of transistors M8 and M9 and current source circuit IBIAS3 generates a fixed bias voltage on the gate of transistor M7. The gain of the loop formed by transistors M4-M6 in tail current control circuit 250 for the example of FIG. 4 is given by:

$$Gain of loop = \frac{{g}_{ds , bias}}{{g}_{m , bias 1}} \qquad ( Eq . 14 )$$

The value of g_{ds,bias} in Eq. (14) is the sum of g_{ds,bias2} of transistor M7 and g_{ds,bias1} of transistor M6. The gain of the loop formed by transistors M4-M6 in FIG. 4 is advantageously larger than the gain of the corresponding loop in FIG. 3 due to the inclusion of transistor M7 coupled to transistor M6 thereby causing a further reduction in current iₚₜₐᵢₗ.

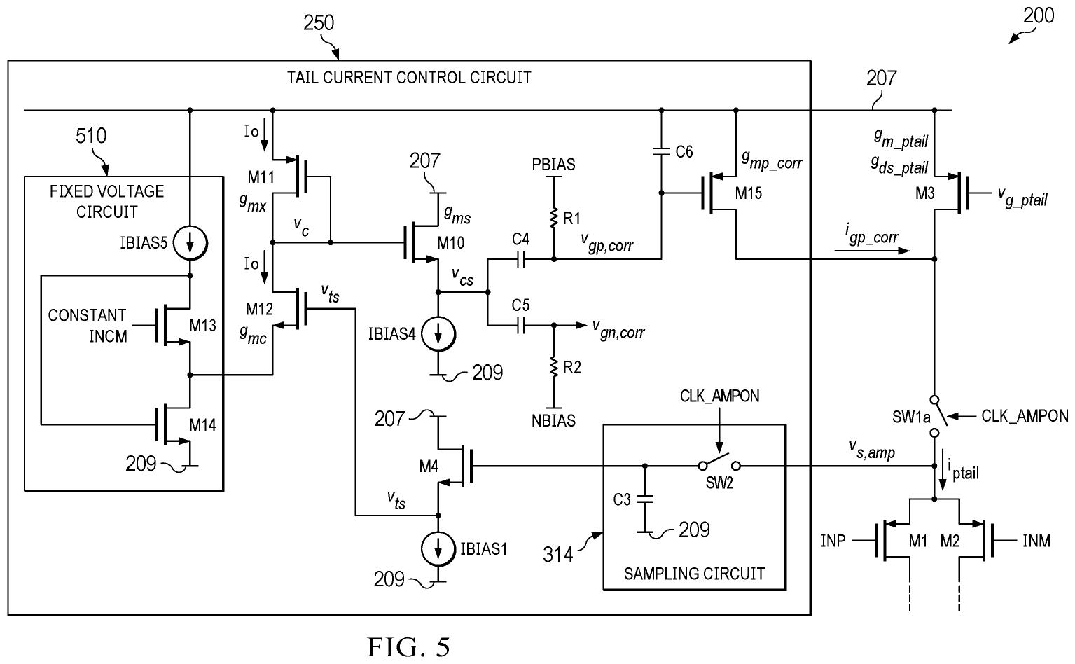

The tail current control circuits 250 in the examples of FIGS. 3 and 4 work well at lower frequencies but not work as well at higher frequencies due to the presence of the relatively large capacitance of capacitor C_{decap}. FIG. 5 is a schematic diagram of a tail current control circuit 250 which may work better at higher frequencies than the tail current control circuits of FIGS. 3 and 4. Tail current control circuit 250 in FIG. 5 includes transistors M4, current source circuit IBIAS1 and sampling circuit 314, as described above with respect to FIG. 3. Tail current control circuit 250 in FIG. 5 also includes a fixed voltage circuit 510, transistors M10, M11, M12, and M15, current source circuit IBIAS4, resistors R1 and R2, capacitors C4, C5, and C6, and current source IBIAS4. Transistors M11 and M15 are PFETs and transistor M12 is an NFET.

Fixed voltage circuit 510 includes a current source circuit IBIAS5 and transistors M13 and M14 (both NFETs) coupled in series between voltage supply terminals 207 and 209. The voltage on the source of transistor M13 and the drain of transistor M14 is a fixed voltage provided to the source of transistor M12. Transistor M11 is a diode-connected transistor with its source coupled to the voltage supply terminal 207 and its drain and gate coupled to the drain of transistor M12. The source of transistor M4 is coupled to the gate of transistor M12, which thus receives voltage vₜₛ, described above. Current source circuit IBIAS4 is coupled to the source of transistor M10 and provides a bias current for transistor M10. One terminal of capacitor C4 is coupled to the source of transistor M10, and the other terminal of capacitor C4 is coupled to the gate of transistor M15. A terminal of resistor R1 is coupled to the gate of transistor M15, and another terminal of resistor R1 is coupled to the reference voltage PBIAS. One terminal of capacitor C6 is coupled to the gate of transistor M15, and another terminal of capacitor C6 is coupled to the voltage supply terminal 207. The similar combination of capacitor C5 and resistor R2 is coupled to the source of transistor M10 and transistor MN15, shown in FIG. 7 and described below, for tail current control through transistor MN3.

The impedance of a capacitor is inversely proportional to the frequency. Accordingly, at low frequency, the impedances of capacitors C4 and C5 are relatively high and the circuit of FIG. 5 has little effect on the control of tail current iₚₜₐᵢₗ. At higher frequency, however, the impedances of capacitors C4 and C5 re relatively low, and the circuit of FIG. 5 helps to increase the common mode gain of amplifier 200. The equation for tail current iₚₜₐᵢₗ is:

$${i}_{ptail} = {g}_{ds \_ ptail} {v}_{s , amp} - {g}_{mp \_ corr} ( \frac{{g}_{mc}}{{g}_{mx}} ) ( \frac{1}{1 + s / {ω}_{c}} ) {v}_{ts} \qquad ( Eq . 15 )$$

where g_{mp,corr} is the gₘ of transistor M15, g_{mc} is the gₘ of transistor M12, gₘₓ is the gₘ of transistor M11, and

$${ω}_{c} = \frac{{g}_{ms}}{( C 6 + {C}_{para} )}$$

where gₘₛ is the gₘ of transistor M10. Accordingly, per Eq. (15), at higher frequencies (ω_{c} is higher), iₚₜₐᵢₗ advantageously is smaller.

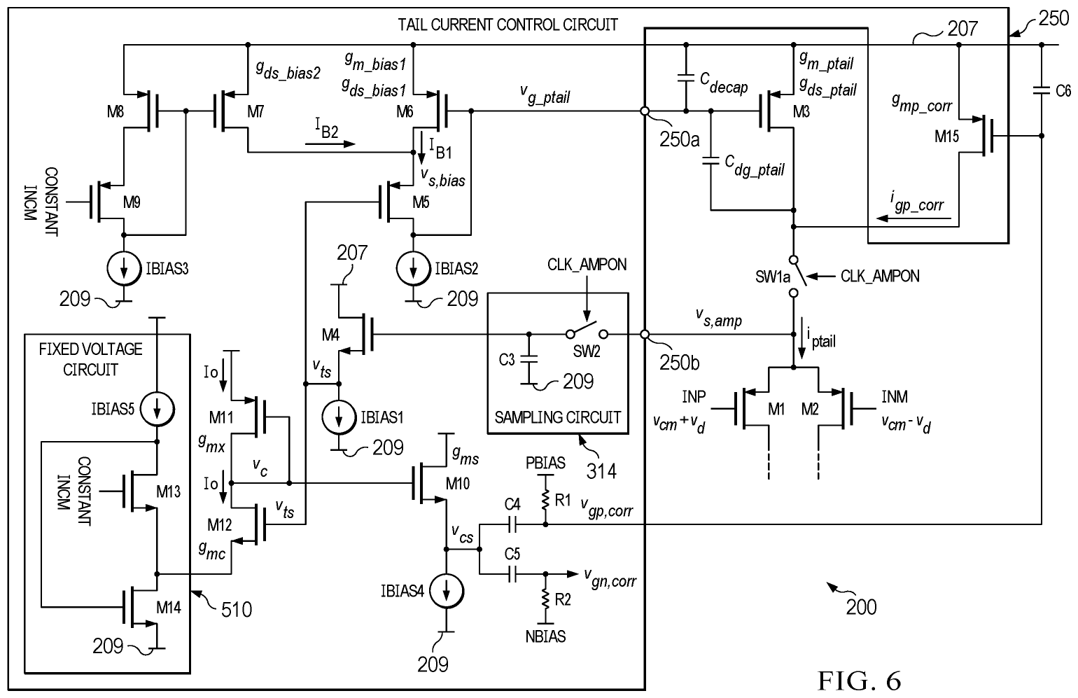

FIG. 6 is a schematic diagram in which the contributions of the examples of FIGS. 3-5 are combined as a tail current control circuit 250 that reduces the common mode gain across a wide range of frequencies. The circuitry of FIG. 6 includes the circuitry of the example tail current control circuits 250 of FIGS. 3-5 combined together in the tail current control circuit 250 shown in FIG. 6. The source of transistor M4 is coupled to the gate of transistor M5, as described above with respect to FIG. 3, and to gate of transistor M12, as described above with respect to FIG. 5. The advantages of tail current control circuit 250 include the advantages described above with respect to FIGS. 3-5.

FIG. 7 is a schematic diagram of tail current control circuit 252 to control the tail current iₙₜₐᵢₗ through transistor MN3. The circuitry of tail current control circuit 252 is largely the same as that described above with respect to tail current control circuits 250 in FIGS. 3-6 but with PFETS replaced with NFETS, and vice versa. For example, PFETs M5, M6, M7, M8, and M15 in FIG. 6 are replaced in FIG. 7 with NFETs MN5, MN6, MN7, MN8, and MN15. Similarly, NFET M4 in FIG. 6 is replaced with PFET MP4 in FIG. 7. Tail current control circuit 252 also includes a sampling circuit 714. Sampling circuit 714 includes a capacitor C37 coupled to a switch SW27. Switch SW27 is coupled between the gate of transistor MP4 and the sources of transistors MN1 and MN2. Sampling circuit 714 samples the voltage at the sources of transistors MN1 and MN2 when switch SW27 is on, which occurs during the hold phase, as described above. The transistors MN5-MN8 and MP4 in FIG. 7 are connected similarly to the corresponding transistors in FIG. 6. The gate of transistor MN3 in FIG. 7 is coupled to the gate of transistor MN6. The drain and source of transistor MN15 is coupled to the drain and source, respectively, of transistor MN3. The gate of transistor MN15 is coupled to capacitor C5 in FIG. 6 to thereby receive the correction voltage v_{gp,corr} for higher frequency operation, as described above.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF”' or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/-10 percent of that parameter or, if the parameter is zero, a reasonable range of values around zero.

Modifications are possible in the described examples, and other examples are possible, within the scope of the claims.

What is claimed is:

1. An amplifier circuit, comprising:
a first transistor having a terminal;
a second transistor having a terminal coupled to the terminal of the first transistor;
a third transistor having a first terminal coupled to the terminals of the first and second transistors and having a control terminal;
a fourth transistor having a control terminal coupled to the terminals of the first and second transistors and to the first terminal of the third transistor, the fourth transistor having a second terminal;
a fifth transistor having a control terminal coupled to the second terminal of the fourth transistor and having second and third terminals; and
a sixth transistor having a control terminal coupled to the control terminal of the third transistor and to the third terminal of the fifth transistor, the sixth transistor having a second terminal coupled to the second terminal of the fifth transistor.

2. The amplifier circuit of claim 1, further comprising:
a first current source circuit coupled to the second terminal of the fourth transistor; and
a second current source circuit coupled to the third terminal of the fifth transistor.

3. The amplifier circuit of claim 1, further comprising a capacitor coupled between the control terminal of the fourth transistor and a voltage supply terminal.

4. The amplifier circuit of claim 3, further comprising a switch coupled between the terminals of the first and second transistors and the control terminal of the fourth transistor.

5. The amplifier circuit of claim 1, wherein the first transistor is a first field effect transistor (FET), the second transistor is a second FET, and the terminals of the first and second transistors are source terminals of the first and second FETs.

6. The amplifier circuit of claim 1, further comprising
a seventh transistor having a terminal coupled to the second terminal of the sixth transistor and having a control terminal;
an eighth transistor having a control terminal coupled to the control terminal of the seventh transistor; and
a current source circuit coupled to the eighth transistor.

7. The amplifier circuit of claim 1, further comprising:
a seventh transistor having a first terminal and a control terminal, the first terminal of the seventh transistor coupled to the first terminal of the third transistor;
an eighth transistor having a first terminal;
a current source circuit coupled between the first terminal of the eighth transistor and a first voltage supply terminal; and
a capacitor coupled between the first terminal of the eighth transistor and the control terminal of the seventh transistor.

8. The amplifier circuit of claim 7, wherein the eighth transistor has a control terminal, and the amplifier circuit further comprises:
a diode-connected transistor coupled between a voltage supply terminal and the control terminal of the eighth transistor; and
a ninth transistor having a first terminal coupled to the diode-connected transistor and having a control terminal coupled to the second terminal of the fourth transistor.

9. The amplifier circuit of claim 8, wherein the ninth transistor has a second terminal, and the amplifier circuit further comprises a fixed voltage circuit having an output coupled to the second terminal of the ninth transistor.

10. The amplifier circuit of claim 6, further comprising:
a ninth transistor having a first terminal and a control terminal, the first terminal of the ninth transistor coupled to the first terminal of the third transistor;
a tenth transistor having a first terminal;
a current source circuit coupled between the first terminal of the tenth transistor and a first voltage supply terminal; and
a capacitor coupled between the first terminal of the tenth transistor and the control terminal of the ninth transistor.

11. A data converter, comprising:
a first stage circuit having an output;
a second stage circuit having an input coupled to the output;
an amplifier having an input coupled to the output of the first stage and having an output coupled to the input of the second stage, the amplifier including:
a first transistor having a first terminal and having a control terminal coupled to the input of the amplifier;
a second transistor having a first terminal coupled to the first terminal of the first transistor and having a control terminal coupled to the input of the amplifier;
a third transistor having a first terminal coupled to the first terminals of the first and second transistors and having a control terminal;
a fourth transistor having a control terminal coupled to the first terminals of the first and second transistors and to the first terminal of the third transistor, the fourth transistor having a second terminal;
a fifth transistor having a control terminal coupled to the second terminal of the fourth transistor and having second and third terminals; and
a sixth transistor having a control terminal coupled to the control terminal of the third transistor and to the third terminal of the fifth transistor, the sixth transistor having a second terminal coupled to the second terminal of the fifth transistor.

12. The data converter of claim 11, further comprising:
a first current source circuit coupled to the second terminal of the fourth transistor; and
a second current source circuit coupled to the third terminal of the fifth transistor.

13. The data converter of claim 11, further comprising a capacitor coupled between the control terminal of the fourth transistor and a voltage supply terminal.

14. The data converter of claim 13, further comprising a switch coupled between the first terminals of the first and second transistors and the control terminal of the fourth transistor.

15. The data converter of claim 11, wherein the first transistor is a first field effect transistor (FET), the second transistor is a second FET, and the first terminals of the first and second transistors are source terminals of the first and second FETs.

16. The data converter of claim 11, further comprising
a seventh transistor having a terminal coupled to the second terminal of the sixth transistor and having a control terminal;
an eighth transistor having a control terminal coupled to the control terminal of the seventh transistor; and
a current source circuit coupled to the eighth transistor.

17. The data converter of claim 11, further comprising:
a seventh transistor having a first terminal and a control terminal, the first terminal of the seventh transistor coupled to the first terminal of the third transistor;
an eighth transistor having a first terminal;
a current source circuit coupled between the first terminal of the eighth transistor and a first voltage supply terminal; and
a capacitor coupled between the first terminal of the eighth transistor and the control terminal of the seventh transistor.

18. A data converter, comprising:
a first stage circuit having an output;
a second stage circuit having an input coupled to the output;
an amplifier having an input coupled to the output of the first stage circuit and having an output coupled to the input of the second stage, the amplifier including:
a first transistor having a first terminal and having a control terminal coupled to the input of the amplifier;
a second transistor having a first terminal coupled to the first terminal of the first transistor and having a control terminal coupled to the input of the amplifier;
a third transistor having a first terminal coupled to the first terminals of the first and second transistors and having a control terminal; and
a tail current control circuit having a first terminal coupled to the control terminal of the third transistor and having a second terminal coupled to the first terminals of the first and second transistors, the tail current control circuit configured to adjust a tail current through the third transistor based on a voltage at the first terminals of the first and second transistors.

19. The data converter of claim 18, wherein the tail current control circuit comprises:
a fourth transistor having a control terminal coupled to the first terminals of the first and second transistors and to the first terminal of the third transistor, the fourth transistor having a second terminal;
a fifth transistor having a control terminal coupled to the second terminal of the fourth transistor and having second and third terminals; and
a sixth transistor having a control terminal coupled to the control terminal of the third transistor and to the third terminal of the fifth transistor, the sixth transistor having a second terminal coupled to the second terminal of the fifth transistor.

20. The data converter of claim 19, further comprising
a seventh transistor having a terminal coupled to the second terminal of the sixth transistor and having a control terminal;
an eighth transistor having a control terminal coupled to the control terminal of the seventh transistor; and
a current source circuit coupled to the eighth transistor.

21. The data converter of claim 19, further comprising:
a seventh transistor having a first terminal, a second terminal, and a control terminal;
an eighth transistor having a terminal;
a current source circuit coupled between the terminal of the eighth transistor and a first voltage supply terminal; and
a capacitor coupled between the terminal of the eighth transistor and the control terminal of the seventh transistor.
